(19) United States
(12) Patent Application Publication
(10) Pub. No.: US 2008/0121928 A1
(43) Pub. Date: May 29, 2008

(54) Semiconductor photocathode

(75) Inventors: Minoru Niigaki, Hamamatsu-shi (JP); Kazutoshi Nakajima, Hamamatsu-shi (JP); Toru Hirohata, Hamamatsu-shi (JP); Hirofumi Kan, Hamamatsu-shi (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K.

(21) Appl. No.: 11/987,216

(22) Filed: Nov. 28, 2007

(30) Foreign Application Priority Data
Nov. 29, 2006 (JP) P2006-322345

(51) Int. Cl. H01L 31/0336

(52) U.S. Cl. 257/184; 257/E31.005

(57) ABSTRACT

A semiconductor photocathode has first and second III-V compound semiconductor layers doped with a p-type impurity and joined to each other to make a heterojunction. The second III-V compound semiconductor layer functions as a light absorbing layer, an energy gap of the second III-V compound semiconductor layer is smaller than that of the first III-V compound semiconductor layer, and Be or C is used as the p-type dopant in each semiconductor layer. At this time, the second III-V compound semiconductor layer may be deposited on the first III-V compound semiconductor layer. The first III-V compound semiconductor layer and the second III-V compound semiconductor layer may contain at least one from each group of (In, Ga, Al) and (As, P, N).

### BACKGROUND OF THE INVENTION

1. Field of the Invention

The present invention relates to a semiconductor photocathode.

2. Related Background Art

Conventionally, for example, zinc (Zn) is used as a p-type dopant in growth of thin films of III-V compound semiconductors. At this time, there arises a problem that abnormal diffusion of Zn as the p-type impurity occurs when the concentration of the p-type impurity is, for example, as high as about 1×10²⁰ cm⁻³ or more. Patent Documents 1-5 point out this problem and describe that the problem is solved by using beryllium (Be) or carbon (C) as the p-type dopant.

On the other hand, there are known semiconductor photocathodes, for example, consisting of a stack of thin films of III-V compound semiconductors. The semiconductor photocathodes of this type are used in measuring devices such as photodetectors, and include the known transmission type photocathodes, for example, as described in Patent Document 6.
[Patent document 1] Japanese Patent No. 3224057
[Patent document 2] Japanese Patent No. 2646966
[Patent document 3] Japanese Patent No. 2761264
[Patent document 4] Japanese Patent Application Laid-open No. H5-136397
[Patent document 5] Japanese Patent Application Laid-open No. 2001-36195
[Patent Document 6] Japanese Patent Application Laid-open No. H9-199075

### [Disclosure of the Invention]

### [Problem to be Solved by the Invention]

Incidentally, in growth of thin films of III-V compound semiconductors for fabrication of a semiconductor photocathode, the concentration of the p-type impurity needs to be, for example, as low as about 1×10¹⁸ cm⁻³ or less, different from the situation noted in Patent Documents 1-5 above. If in this case the abnormal diffusion of the p-type impurity occurs in a III-V compound semiconductor, it becomes infeasible to accurately control the carrier concentration in the p-type compound semiconductor layer and, as a result, there arises a problem that the semiconductor photocathode including the p-type compound semiconductor layer fails to hold characteristics as expected.

Therefore, the present invention has been accomplished in view of the above-described circumstances and an object of the invention is to provide a semiconductor photocathode capable of preventing the abnormal diffusion of the p-type impurity.

### SUMMARY OF THE INVENTION

### [Means for Solving the Problem]

The inventor conducted elaborate research and found out the fact as described below. Namely, the inventor discovered the following fact: “In a semiconductor device, e.g., a semiconductor photocathode or the like, using Zn as a p-type dopant and having a heterostructure, where a semiconductor layer of a p-type binary compound semiconductor (which will also be referred to as a “binary semiconductor layer”) doped with Zn in the low concentration of not more than 1×10¹⁸ cm⁻³ is deposited on a III-V compound semiconductor layer of a p-type ternary compound semiconductor or a III-V compound semiconductor layer of a p-type quaternary compound semiconductor (which will also be referred to as a “ternary/quaternary semiconductor layer”) doped with Zn in the low concentration of not more than 1×10¹⁸ cm⁻³, the predetermined Zn doping concentration as designed is achieved as proved by analysis of concentration distribution after deposition. However, when the ternary/quaternary semiconductor layer is deposited on the binary semiconductor layer contrary to the above, the abnormal diffusion of Zn occurs in the binary semiconductor layer as proved by analysis of concentration distribution after deposition and the predetermined Zn doping concentration as designed is not achieved in the binary semiconductor layer.”

The inventor conducted further elaborate research and further discovered the following fact: “When a semiconductor device is formed in a configuration wherein it has a first III-V compound semiconductor layer and a second III-V compound semiconductor layer making a heterojunction and wherein the energy gap of the second III-V compound semiconductor layer is smaller than that of the first III-V compound semiconductor layer, the abnormal diffusion of the p-type impurity does not occur from a growth system or growth conditions, but occurs from the essential problems arising from the semiconductor heterostructure and the type of the p-type impurity.” There are no prior art documents pointing out this problem of abnormal diffusion (e.g., none of the prior patent documents including Patent Documents 1-5 above describes it) and no reason for it has been elucidated. The present invention has been accomplished on the basis of the new findings as described above and in order to prevent the abnormal diffusion of the p-type impurity in the low concentration region in the case where the ternary/quaternary semiconductor layer is deposited on the binary semiconductor layer.

Specifically, a semiconductor photocathode of the present invention comprises a first III-V compound semiconductor layer and a second III-V compound semiconductor layer doped with a p-type impurity and joined to each other to make a heterojunction. The second III-V compound semiconductor layer functions as a light absorbing layer and an energy gap of the second III-V compound semiconductor layer is smaller than an energy gap of the first III-V compound semiconductor layer. Be or C is used as the p-type dopant in each of the III-V compound semiconductor layers. In this case, the second III-V compound semiconductor layer may be deposited on the first III-V compound semiconductor layer. The first III-V compound semiconductor layer and the second III-V compound semiconductor layer may contain at least one from each group of (In, Ga, Al) and (As, P, N). At this time, preferably, the first III-V compound semiconductor layer is a III-V compound semiconductor layer of a binary compound semiconductor and the second III-V compound semiconductor layer is a III-V compound semiconductor layer of a ternary compound semiconductor or a quaternary compound semiconductor. The first III-V compound semiconductor layer and the second III-V compound semiconductor layer may be grown by molecular beam epitaxy (MBE). The first III-V compound semiconductor layer and the second III-V compound semiconductor layer may be doped with the p-type impurity in a low concentration of not more than 1×10¹⁸ cm⁻³.

Since the semiconductor photocathode of the present invention as described above uses Be or C, which has the diffusion coefficient smaller than that of Zn, i.e., which has the atomic radius smaller than that of Zn, as the p-type dopant in the first III-V compound semiconductor layer and the second III-V compound semiconductor layer, it is able to prevent the abnormal diffusion of the p-type dopant in the first III-V compound semiconductor layer.

Another semiconductor photocathode of the present invention is a semiconductor photocathode comprising: a transparent substrate: an entrance electrode formed above the transparent substrate and permitting passage of light having passed through the transparent substrate; a light absorbing layer of a p-type III-V compound semiconductor material formed above the entrance electrode and adapted for exciting photoelectrons in response to incidence of light; a window layer of a p-type III-V compound semiconductor material interposed between the entrance electrode and the light absorbing layer, having an energy gap larger than that of the light absorbing layer, comprised of a semiconductor material to be lattice-matched with the light absorbing layer, and having a thickness of not less than 10 nm nor more than 200 nm; an electron transport layer of a p-type III-V compound semiconductor material formed on the light absorbing layer, comprised of a semiconductor material to be lattice-matched with the light absorbing material, and adapted for emitting the photoelectrons excited in the light absorbing layer, from a surface thereof to the outside; and an emission electrode formed above the electron transport layer, and Be or C is preferably used as an impurity in the p-type III-V compound semiconductor materials.

In this configuration, the window layer to be lattice-matched with the semiconductor material of the light absorbing layer is formed on the light entrance side, but the thickness thereof is very small. For this reason, in a state in which a bias voltage is applied, light having passed through the transparent substrate, in a wide wavelength band from the ultraviolet region to the near-infrared region, travels through the entrance electrode, and thereafter is scarcely blocked by the window layer, and the light enters the light absorbing layer to excite photoelectrons. Then the excited photoelectrons are emitted through the electron transport layer to the outside. Therefore, the semiconductor photocathode is obtained with sensitivity to the light in the wide wavelength band.

Furthermore, Be or C, which has the diffusion coefficient smaller than that of Zn, i.e., which has the atomic radius smaller than that of Zn, is used as the impurity in the p-type III-V compound semiconductor materials, whereby it is feasible to prevent the abnormal diffusion of the p-type impurity in the electron transport layer.

Another semiconductor photocathode of the present invention is a semiconductor photocathode comprising: a transparent substrate: an entrance electrode formed above the transparent substrate and permitting passage of light having passed through the transparent substrate; a light absorbing layer of a p-type III-V compound semiconductor material formed above the entrance electrode and adapted for exciting photoelectrons in response to incidence of light; a window layer of a p-type III-V compound semiconductor material interposed between the entrance electrode and the light absorbing layer, having an energy gap larger than that of the light absorbing layer, comprised of a semiconductor material to be lattice-matched with the light absorbing layer, and having a thickness of not less than 10 nm nor more than 200 nm; an electron transport layer of a p-type III-V compound semiconductor material formed on the light absorbing layer, comprised of a semiconductor material to be lattice-matched with the light absorbing material, and adapted for emitting the photoelectrons excited in the light absorbing layer, from a surface thereof to the outside; a contact layer of an n-type III-V compound semiconductor material formed on the electron transport layer; and an emission electrode formed on the contact layer, and Be or C is preferably used as an impurity in the p-type III-V compound semiconductor materials.

As the contact layer is provided as described above, the contact resistance is lowered between the electron transport layer and the emission electrode, whereby the bias voltage can be effectively applied.

Furthermore, in the case where the contact layer is provided, Be or C, which has the diffusion coefficient smaller than that of Zn, i.e., which has the atomic radius smaller than that of Zn, is used as the impurity in the p-type III-V compound semiconductor materials, whereby it is feasible to prevent the abnormal diffusion of the p-type impurity in the electron transport layer.

In the semiconductor photocathode, the entrance electrode may be a metal material layer having a thickness of not less than 5 nm nor more than 100 nm. This configuration permits the entrance electrode to transmit light in a wide wavelength band, while having the thickness that can be controlled in production, even in the case where the entrance electrode is made of the metal material.

The entrance electrode may be a metal material layer having a thickness of not less than 10 nm nor more than 50 nm. This configuration permits the entrance electrode to transmit light in a wider wavelength band toward the light absorbing layer, while uniformly applying the bias voltage to the semiconductor photocathode, in the case where the entrance electrode is made of the metal material.

The entrance electrode may be comprised of a metal material having an aperture. This configuration permits the entrance electrode to transmit light through the aperture toward the light absorbing layer even in the case where the entrance electrode is the metal material layer.

The entrance electrode may be comprised of at least one transparent electroconductive material selected from a group consisting of ITO, ZnO, In₂O₃, and SnO₂. When the entrance electrode is comprised of the transparent electroconductive material to transmit light, it is able to pass the light having passed through the transparent substrate, toward the light absorbing layer, while having the function as an electrode.

In the semiconductor photocathode, the thickness of the window layer may be not less than 20 nm nor more than 100 nm. When the thickness of the window layer is defined in this range, it becomes feasible to form the window layer in the thickness, in which it is easy to form a uniform layer, and to apply the bias voltage well, and the window layer is able to suitably transmit light in a wide wavelength band.

The semiconductor photocathode may further comprise an insulating film interposed between the transparent substrate and the entrance electrode. When the insulating film is provided in this manner, it provides an effect of enhancing adhesion between the transparent substrate and the semiconductor material.

The semiconductor photocathode may further comprise an antireflection film interposed between the transparent substrate and the entrance electrode. When the antireflection film is provided in this manner, the reflectance is reduced at a desired wavelength for light incident to the light absorbing layer, and the efficiency of emission of photoelectrons can be increased.

### [Effect of the Invention]

The present invention enables the prevention of the abnormal diffusion of the p-type impurity. This permits us to accurately control the carrier concentration in the deposited semiconductor layer, so that the semiconductor photocathode fabricated with the semiconductor layer can hold characteristics as expected.

### BRIEF DESCRIPTION OF THE DRAWINGS

### [Brief Description of the Drawings]

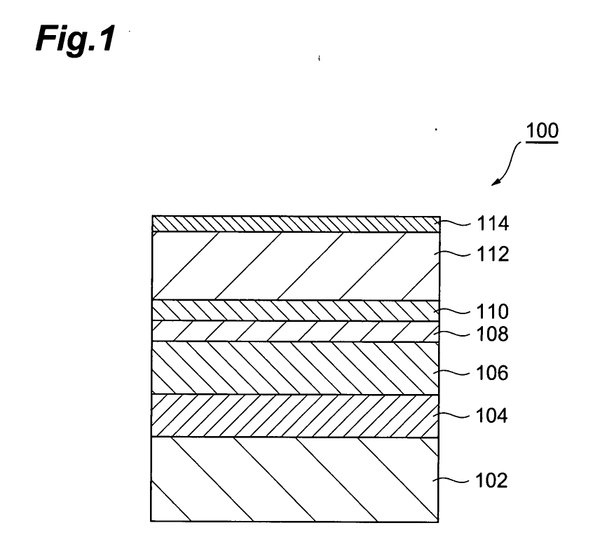

FIG. 1 is a sectional view showing a layer structure of a semiconductor device 100 according to the first embodiment.

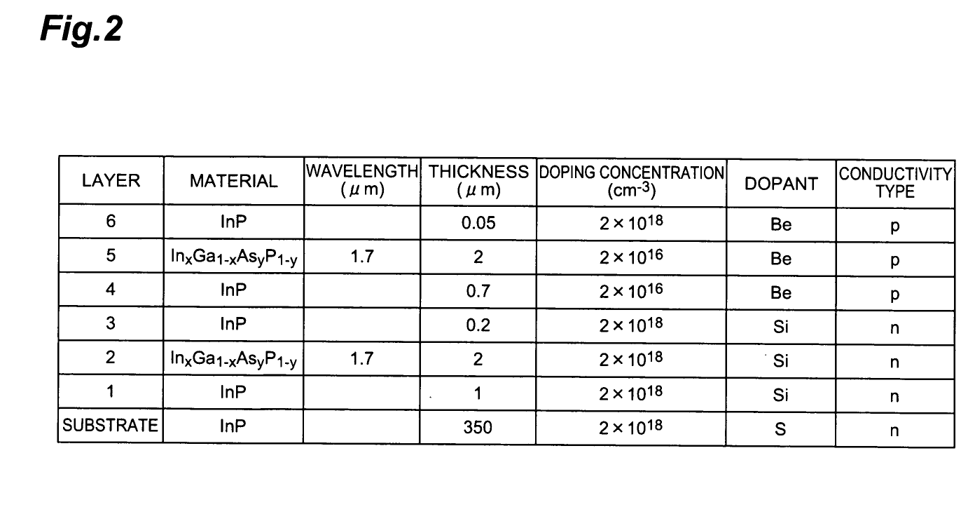

FIG. 2 is a drawing showing a table of designed particulars about the semiconductor device 100 of the first embodiment.

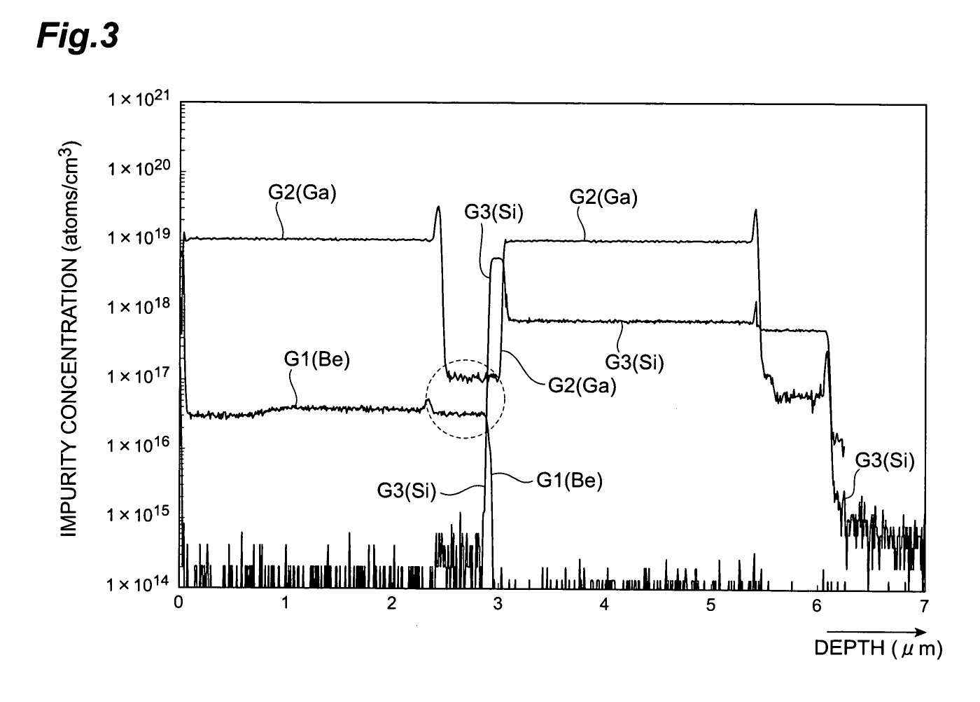

FIG. 3 is a drawing showing the result of measurement of concentration distribution of Be atoms by SIMS, with the semiconductor device 100 of the first embodiment.

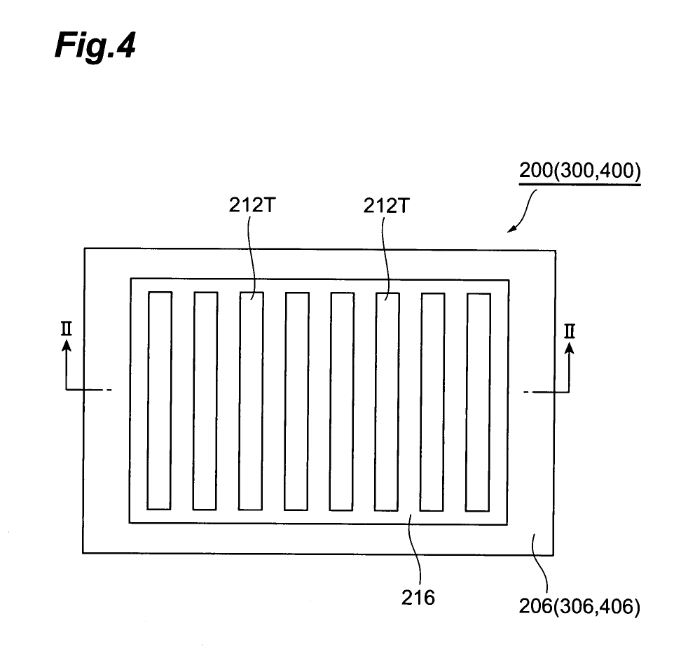

FIG. 4 is a plan view of a semiconductor photocathode 200 according to the second embodiment.

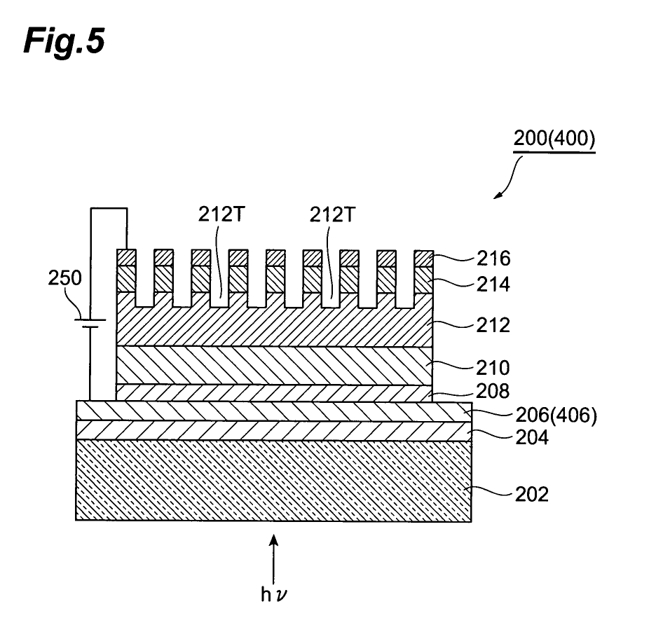

FIG. 5 is a sectional view of the semiconductor photocathode 200 along line II-II in FIG. 4.

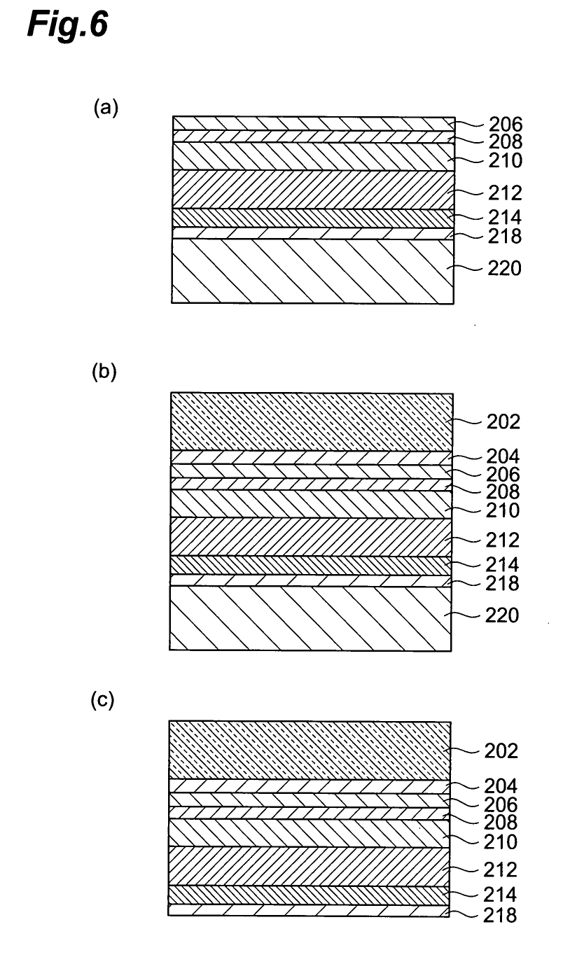

FIG. 6 is sectional views showing a production process of the semiconductor photocathode 200 according to the second embodiment.

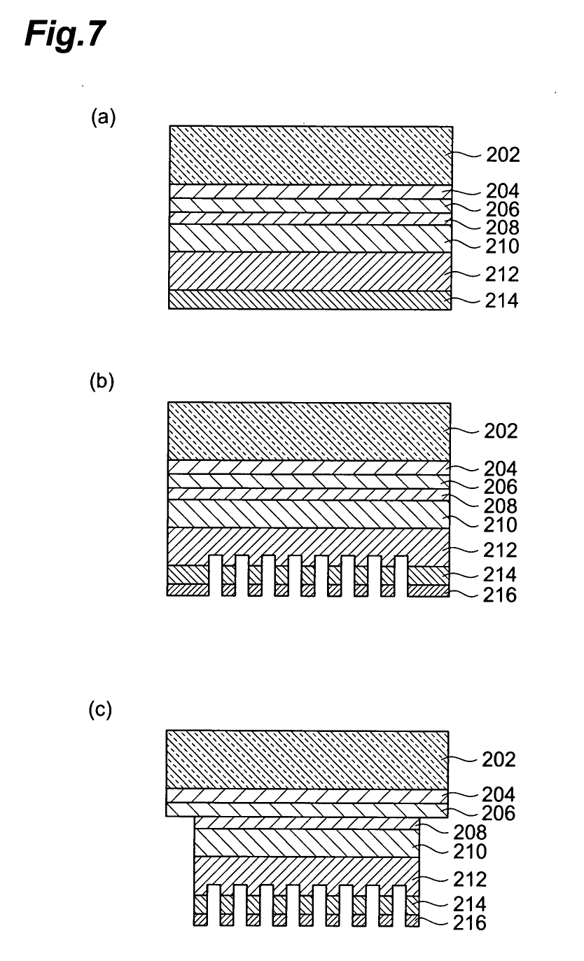

FIG. 7 is sectional views showing a production process of the semiconductor photocathode 200 according to the second embodiment.

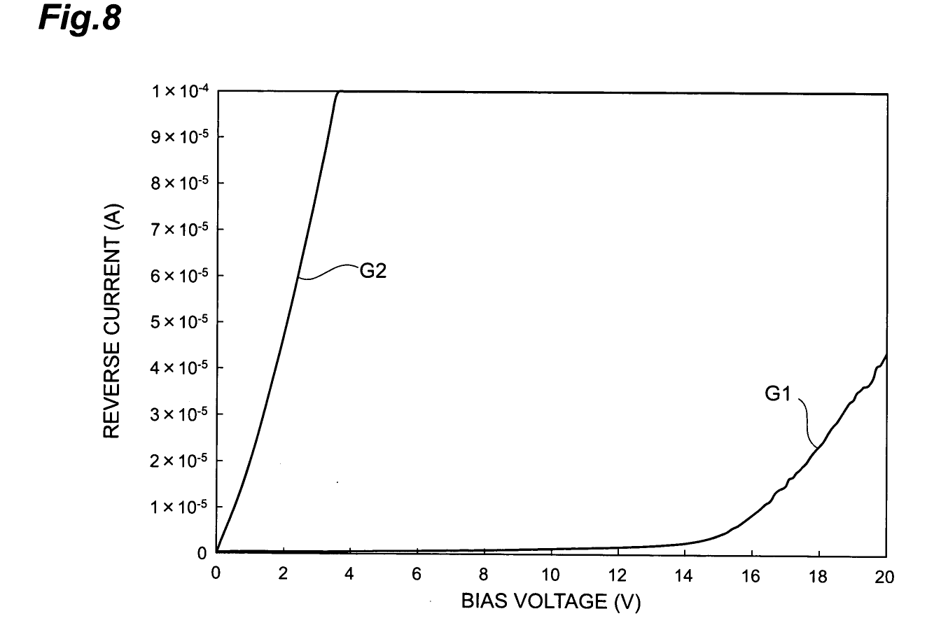

FIG. 8 is a drawing showing characteristic data of the semiconductor photocathode 200 according to the second embodiment.

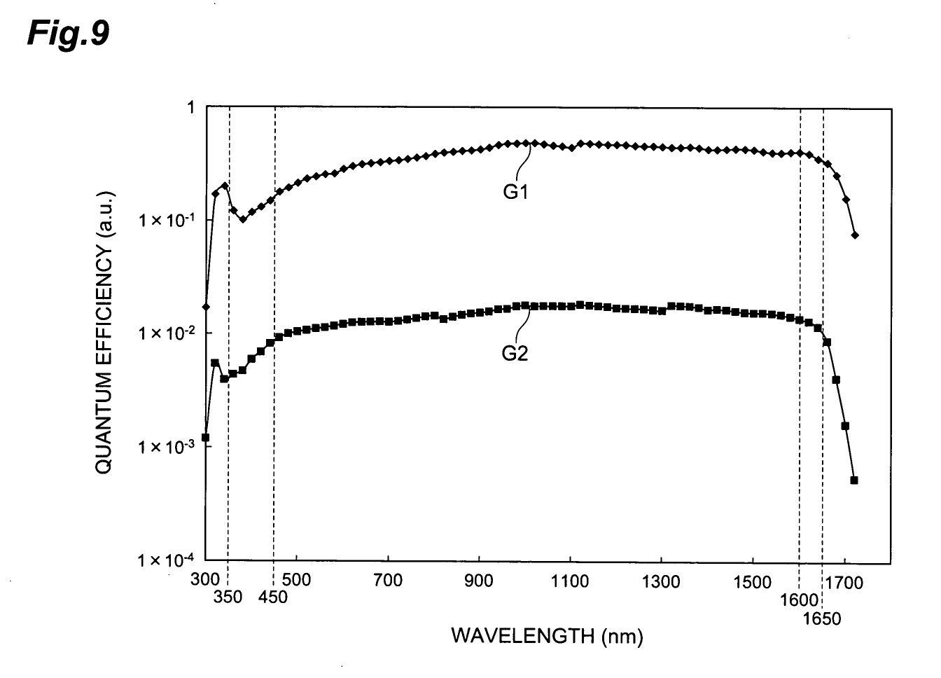

FIG. 9 is a drawing showing characteristic data of the semiconductor photocathode 200 according to the second embodiment.

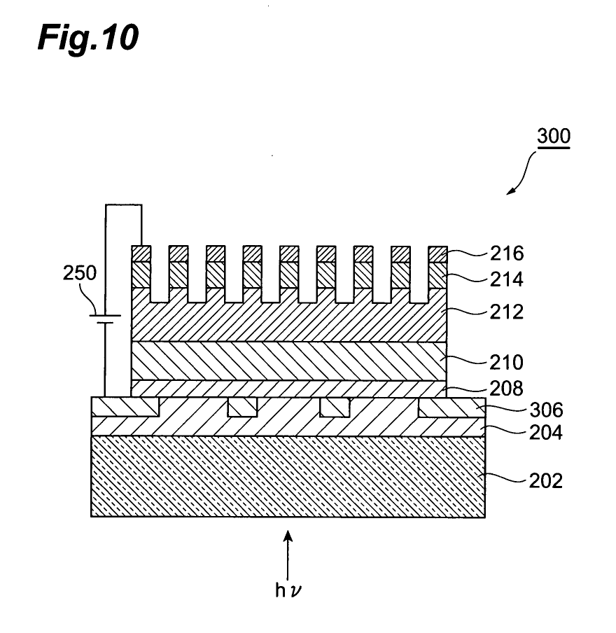

FIG. 10 is a sectional view of a semiconductor photocathode 300 according to the third embodiment.

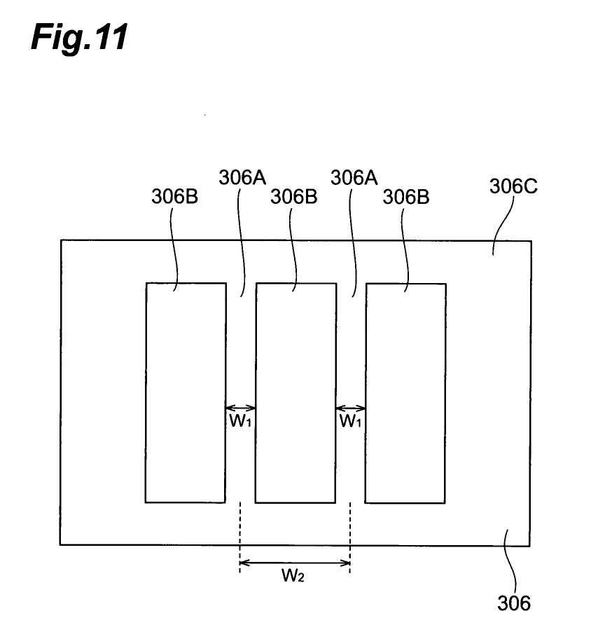

FIG. 11 is a plan view of an entrance electrode 306 in the semiconductor photocathode 300 according to the third embodiment.

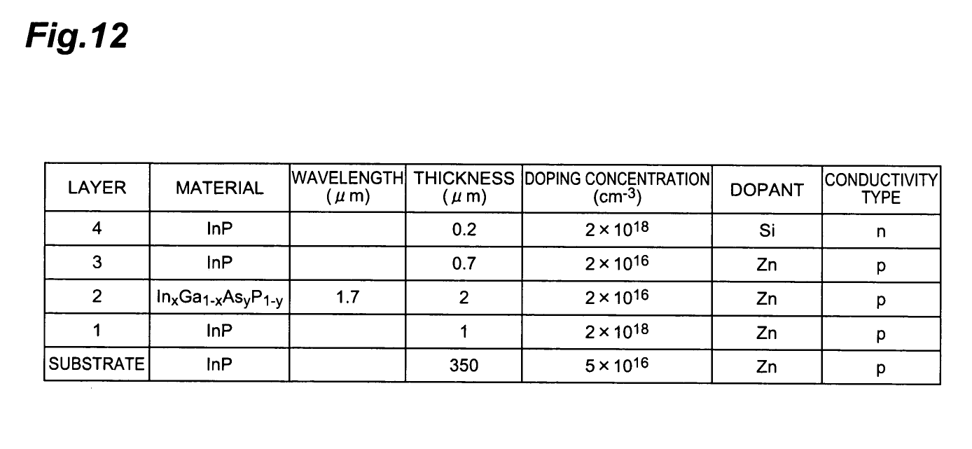

FIG. 12 is a drawing showing a table of designed particulars about a first prototype device.

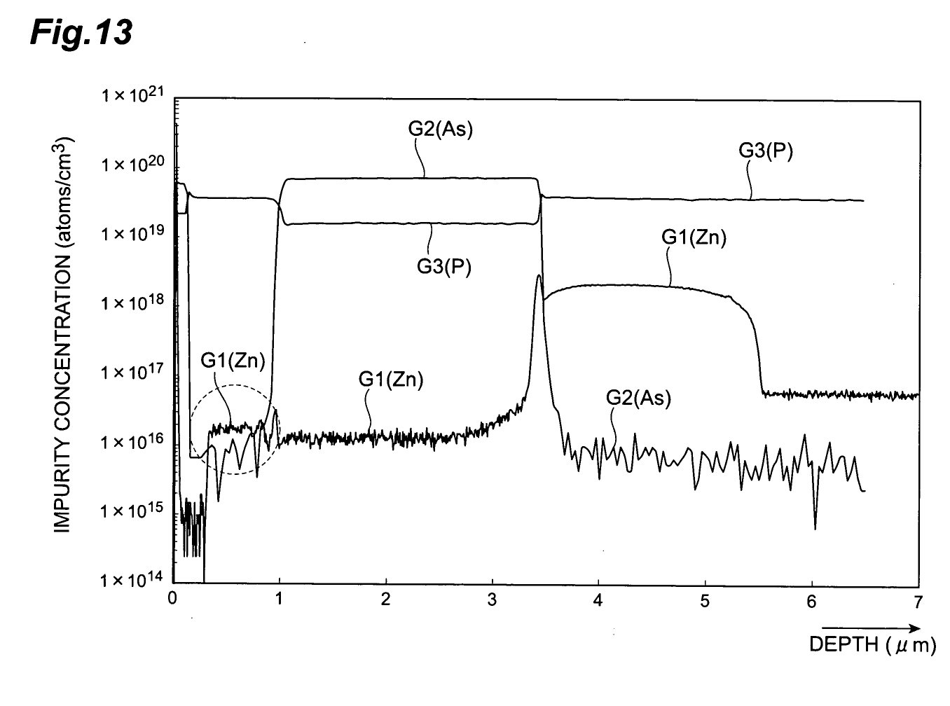

FIG. 13 is a drawing showing the result of measurement of concentration distribution of Zn atoms by SIMS, with the first prototype device.

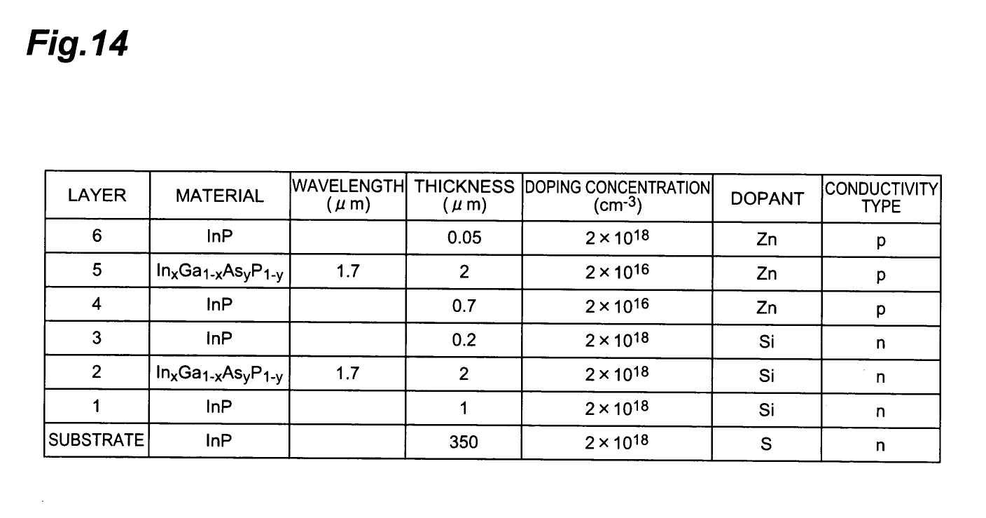

FIG. 14 is a drawing showing a table of designed particulars about a second prototype device.

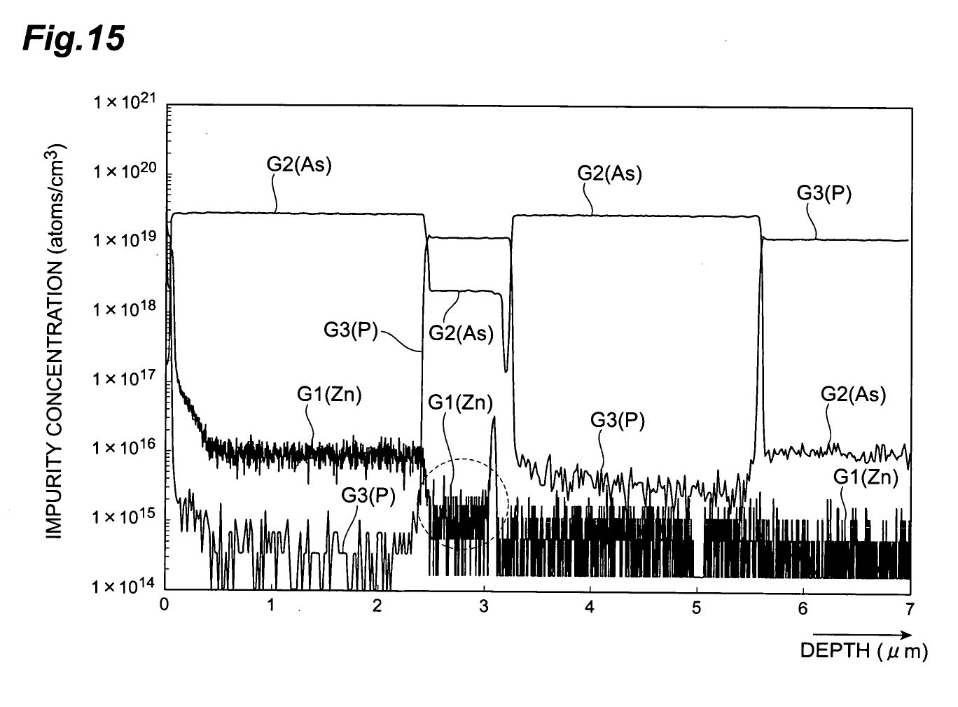

FIG. 15 is a drawing showing the result of measurement of concentration distribution of Zn atoms by SIMS, with the second prototype device.

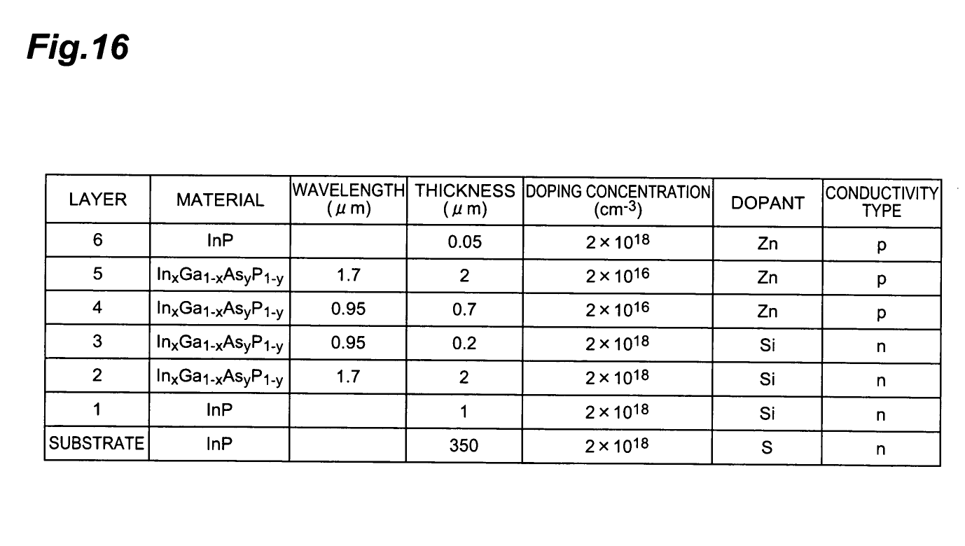

FIG. 16 is a drawing showing a table of designed particulars about a third prototype device.

### DESCRIPTION OF REFERENCE SYMBOLS

100 semiconductor device; 102 n-type InP substrate; 104 n-type InP semiconductor layer (first layer); 106 n-type InGaAsP semiconductor layer (second layer); 108 n-type InP semiconductor layer (third layer); 110 p-type InP semiconductor layer (fourth layer); 112 p-type InGaAsP semiconductor layer (fifth layer); 114 p-type InP semiconductor layer (sixth layer); 200 semiconductor photocathode; 202 transparent substrate; 204 intermediate film; 206 entrance electrode; 208 window layer; 210 light absorbing layer; 212 electron transport layer; 212T apertures; 214 contact layer; 216 emission electrode; 218 etching stop layer; 220 substrate; 250 bias power supply; 300 semiconductor photocathode; 306 entrance electrodes; 306A linear portions; 306B apertures; 306C edge portion; 400 semiconductor photocathode; 406 entrance electrode.

### DESCRIPTION OF THE PREFERRED EMBODIMENTS

### [Best Mode for Carrying out the Invention]

Preferred embodiments of the semiconductor photocathode according to the present invention will be described below in detail with reference to the accompanying drawings. The same elements will be denoted by the same reference symbols throughout the description of the drawings, without redundant description. It is also noted that dimensional ratios in the drawings do not always agree with those in the description.

### First Embodiment

A semiconductor device 100 according to the first embodiment of the present invention will be described. FIG. 1 is a sectional view showing a layer structure of the semiconductor device 100. As described later, this semiconductor device 100 can be used, for example, as a transmission type semiconductor photocathode. As shown in FIG. 1, the semiconductor device 100 has the structure in which the following layers are stacked in the order named, on an n-type InP substrate 102: n-type InP semiconductor layer 104 (first layer); n-type InGaAsP semiconductor layer 106 (second layer); n-type InP semiconductor layer 108 (third layer); p-type InP semiconductor layer 110 (fourth layer, which is the first III-V compound semiconductor layer of the p-type binary compound semiconductor); p-type InGaAsP semiconductor layer 112 (fifth layer, which is the second III-V compound semiconductor layer of the p-type ternary compound semiconductor or the p-type quaternary compound semiconductor); and p-type InP semiconductor layer 114 (sixth layer).

FIG. 2 is a drawing showing a table of the designed particulars of the materials, thicknesses, etc. of the respective layers, as an example for fabrication of the semiconductor device 100. In the semiconductor device 100, as shown in FIG. 2, the InP substrate 102 is so designed that its thickness is 350 μm and that the doping concentration of sulfur (S) is 2×10¹⁸ cm⁻³. The n-type InP semiconductor layer 104 of the first layer is so designed that its thickness is 1 μm and that the doping concentration of Si is 2×10¹⁸ cm⁻³. The n-type InGaAsP semiconductor layer 106 of the second layer is so designed that its wavelength corresponding to the energy gap at room temperature is 1.7 μm, that its thickness is 2 μm, and that the doping concentration of Si is 2×10¹⁸ cm⁻³. The n-type InP semiconductor layer 108 of the third layer is so designed that its thickness is 0.2 μm and that the doping concentration of Si is 2×10¹⁸ cm⁻³.

The p-type InP semiconductor layer 110 of the fourth layer is so designed that its thickness is 0.7 μm and that the doping concentration of Be is 2×10¹⁶ cm⁻³. The p-type InGaAsP semiconductor layer 112 of the fifth layer is so designed that its wavelength is 1.7 μm, that the thickness is 2 μm, and that the doping concentration of Be is 2×10¹⁶ cm⁻³. The energy gap of this fifth layer is designed to be smaller than that of the fourth layer. The p-type InP semiconductor layer 114 of the sixth layer is so designed that its thickness is 0.05 μm and that the doping concentration of Be is 2×10¹⁸ cm⁻³.

Each of the layers was epitaxially grown in order based on the above-described design by MBE to fabricate the semiconductor device 100 of the present embodiment as shown in FIG. 1. FIG. 3 is a drawing showing the result of measurement to measure the concentration distribution of Be atoms as the p-type dopant by secondary ion mass spectroscopy (which will be referred to hereinafter as “SIMS”), with the fabricated semiconductor device 100. FIG. 3 shows the concentration distribution of Be atoms in the depth direction from the sixth layer side of the top layer to the substrate side of the bottom layer in the semiconductor device 100. Namely, the upper surface of the sixth layer in the semiconductor device 100 has the depth equivalent to “0 μm” in FIG. 3. In FIG. 3, the concentration distribution of Be atoms is indicated by graph G1. In order to identify the interfaces between the layers, the concentration distribution of Ga atoms is indicated by graph G2 and the concentration distribution of Si atoms by graph G3.

As shown in FIG. 3, the measured doping concentrations of Be in the respective layers agree with the doping concentrations of Be (in the fifth column in FIG. 2) according to the design as shown in FIG. 2. Particularly, noting the part of the p-type InP layer of the fourth layer encircled by a dotted line in FIG. 3, it can be confirmed that the atomic concentration of Be is the predetermined value of 2×10¹⁶ cm⁻³ as designed.

The above result shown in FIG. 3 is also achieved in the following cases, as well as in the above-described case where the fourth layer is the p-type InP semiconductor layer and where the fifth layer is the p-type InGaAsP semiconductor layer. Namely, the result similar to the result shown in FIG. 3 is achieved in cases where the fourth layer and the fifth layer contain at least one from each group of (In, Ga, Al) and (As, P, N) and where the energy gap of the fourth layer is larger than that of the fifth layer. In addition, the result similar to the result shown in FIG. 3 is also achieved in cases where the fourth layer is a semiconductor layer of a binary compound semiconductor and where the fifth layer is a semiconductor layer of a ternary compound semiconductor. Furthermore, the result similar to the result shown in FIG. 3 is also achieved in cases where C is used as the p-type dopant, as well as in the cases where Be is used as the p-type dopant.

In the semiconductor device 100 of the present embodiment as described above, Be or C having the diffusion coefficient smaller than that of Zn, i.e., having the atomic radius smaller than that of Zn is used as the p-type dopant in the fourth layer and the fifth layer, which can prevent the abnormal diffusion of the p-type dopant in the fourth layer.

In the present embodiment, each of the layers constituting the semiconductor device 100 is epitaxially grown by MBE. The reason for it is that the MBE process is a preferred epitaxial growth method using Be as the p-type dopant.

### Second Embodiment

Next, the second embodiment of the present invention will be described. The semiconductor device 100 described through the first embodiment can be used as a semiconductor photocathode. FIG. 4 is a plan view showing a transmission type semiconductor photocathode 200 according to the second embodiment of the present invention, as an example of the semiconductor photocathode, and FIG. 5 is a sectional view along line II-II in FIG. 4.

(Overall Description of Semiconductor Photocathode)

The semiconductor photocathode 200 has a transparent substrate 202, an intermediate film 204 (insulating film or antireflection film), an entrance electrode 206, a window layer 208, a light absorbing layer 210 (the second III-V compound semiconductor layer of the p-type ternary compound semiconductor or the p-type quaternary compound semiconductor), an electron transport layer 212 (the first III-V compound semiconductor layer of the p-type binary compound semiconductor), a contact layer 214, and an emission electrode 216. The window layer 208, light absorbing layer 210, electron transport layer 212, and contact layer 214 are constructed as a semiconductor multilayer film responsible for photoelectric conversion.

The transparent substrate 202 is made of a material without restrictions on the short-wavelength sensitivity edge and transmits incident light hv in a wide wavelength band from the ultraviolet region to the near-infrared region. The material applicable to the transparent substrate 202 is, for example, glass or quartz. The transparent substrate 202 is a portion for maintaining the mechanical strength of the semiconductor photocathode 200 and can be a part of a vacuum container when incorporated in an electron tube.

The intermediate film 204 functions as an insulating film or as an antireflection film and is, for example, a silicon dioxide film in the present embodiment. This intermediate film 204 can be deposited, for example, by plasma CVD (plasma chemical vapor deposition) and bonded to the transparent substrate 202, for example, by thermal compression bond.

The entrance electrode 206 is formed on the transparent substrate 202, and is made as a metal material layer in a very small thickness, and as an electrode on the light entrance side that light having passed through the transparent substrate 202 can pass. This entrance electrode 206 is made of a material, e.g., such as W (tungsten), Mo (molybdenum), Ni (nickel), Ti (titanium), or Cr (chromium) and the thickness thereof is preferably not less than 5 nm nor more than 100 nm and more preferably not less than 10 nm nor more than 50 nm. As an example, the entrance electrode 206 can be made of tungsten in the thickness of 10 nm.

When the entrance electrode 206 is made in this manner, it has the thickness that can be controlled in manufacture as an electrode, and it is able to transmit light reaching the entrance electrode 206 in a wide wavelength band, toward the light absorbing layer 210. It is also able to favorably transmit light in a wide wavelength band from the ultraviolet region to the near-infrared region, while implementing homogeneous application of a bias voltage to the semiconductor photocathode. Particularly, where the thickness is not less than 10 nm nor more than 50 nm, it is feasible to realize more homogeneous film quality and low surface resistance together, which achieves an effect of being capable of forming a homogeneous bias electric field while maintaining high transmittance.

The window layer 208 is formed on the entrance electrode 206 and is made as a layer of a semiconductor material in a very small thickness. This window layer 208 is comprised of a p-type semiconductor material (e.g., InP doped with Be) to be lattice-matched with a semiconductor material of the below-described light absorbing layer 210 and is made as a p-side contact layer having the function of transmitting incident light hv as a window layer and the function of applying the bias voltage. Furthermore, the window layer 208 has the energy gap larger than that of the light absorbing layer 210 as described below, and this causes the window layer 208 to also have the function of preventing photoelectrons generated in the light absorbing layer from diffusing to the transparent substrate side. That a certain crystal is lattice-matched with the semiconductor material of the window layer refers to the following case where the window layer is comprised of InP: the difference between the lattice constant of the crystal and the lattice constant of InP is within ±0.5% with respect to the lattice constant of InP.

The thickness of the window layer 208 is preferably not less than 10 nm nor more than 200 nm and more preferably not less than 20 nm nor more than 100 nm. As an example, the window layer 208 can be made of Be-doped p-type InP in the thickness of 50 nm. When the window layer 208 is made in this manner, it becomes feasible to favorably apply the bias voltage, while securing the thickness easy for a uniform layer to be formed, and the window layer is able to suitably transmit light in a wide wavelength band from the ultraviolet region to the near-infrared region. Particularly, where the thickness of the window layer 208 is not less than 20 nm nor more than 100 nm, there are effects of efficiently transmitting incident light hv, blocking diffusion of photoelectrons excited in the light absorbing layer, toward the entrance electrode, and efficiently transporting the photoelectrons toward the electron transport layer 212. The carrier concentration in the window layer 208 is preferably not less than 1×10¹⁷ cm⁻³ nor more than 1×10¹⁹ cm⁻³. In this case, there is an effect of being capable of applying a uniform bias voltage to the light absorbing layer 210. The material available for the window layer 208 is a semiconductor that is to be lattice-matched with the light absorbing layer 210 and that has the energy gap larger than that of the light absorbing layer 210, in addition to Be-doped p-type InP.

The light absorbing layer 210 is a layer for exciting photoelectrons in response to incident light hv and is formed on the window layer 208. This light absorbing layer 210 is made of a semiconductor material (e.g., Be-doped p-type InGaAs) having the energy gap smaller than that of the window layer 208 and being to be lattice-matched with the window layer 208. The light absorbing layer 210 can be one having the thickness of not less than 20 nm nor more than 5000 nm and the carrier concentration of not less than 1×10¹⁵ cm⁻³ nor more than 1×10¹⁷ cm⁻³. The material available for the light absorbing layer 210 is Be- or C-doped p-type InGaAsP, Be- or C-doped p-type InAlGaAs, or the like, in addition to Be-doped p-type InGaAs. Namely, the material of the light absorbing layer 210 can be a semiconductor layer of a ternary or quaternary compound semiconductor containing at least one element from each group of (In, Ga, Al) and (As, P, N).

The electron transport layer 212 is a layer having the energy gap larger than that of the light absorbing layer 210 and adapted to emit the photoelectrons excited in the light absorbing layer 210, from its surface to the outside and is formed on the light absorbing layer 210. This electron transport layer 212 is made of a semiconductor material (e.g., Be-doped p-type InP) to be lattice-matched with the light absorbing layer 210. The electron transport layer 212 is provided with apertures 212T about 1000 nm wide in a stripe pattern so as to be able to emit electrons to the outside. FIGS. 4 and 5 show the semiconductor photocathode 200 where the apertures 212T are formed in the stripe pattern and where apertures of the same shape are also formed in the contact layer 214 and the emission electrode 216. FIG. 4 shows the case where the apertures are of the stripe pattern, but they may be formed in a mesh pattern; the shape of the apertures is arbitrary as long as the apertures have a uniform shape.

The electron transport layer 212 can be a layer having the thickness of not less than 50 nm nor more than 2000 nm and the carrier concentration as low as 1×10¹⁸ cm⁻³ or less and, particularly, not less than 5×10¹⁵ cm⁻³ nor more than 1×10¹⁷ cm⁻³. The line width of the apertures 212T can be not less than 100 nm nor more than 100000 nm and the pitch of the apertures 212T can be not less than 100 nm nor more than 100000 nm. The material of the electron transport layer 212 can be a semiconductor being to be lattice-matched with the light absorbing layer 210 and having the energy gap larger than that of the light absorbing layer 210, in addition to Be-doped p-type InP. For example, the material of the electron transport layer 212 can be a semiconductor layer of a compound semiconductor containing at least one element from each group of (In, Ga, Al) and (As, P, N), and C can be used as an impurity thereof.

The contact layer 214 is interposed between the electron transport layer 212 and the emission electrode 216 and is made of a semiconductor material to be lattice-matched with the electron transport layer 212. This contact layer 214 is an additional layer that lowers the contact resistance between the electron transport layer 212 and the emission electrode 216 and that implements effective application of the bias voltage, and is made of n-type InP. In the case where the light absorbing layer 210 and the electron transport layer 212 are made of the p-type semiconductor materials and where the contact layer 214 is made of the n-type semiconductor material, the contact layer 214 serves as an n-side contact layer. The contact layer 214 can be a layer having the thickness of not less than 50 nm nor more than 10000 nm and the carrier concentration of 1×10¹⁷ cm⁻³ nor more than 1×10¹⁹ cm⁻³. The material of the contact layer 214 can be a semiconductor that is to be lattice-matched with the light absorbing layer 210 and that has the energy gap larger than that of the light absorbing layer 210, in addition to n-type InP.

The emission electrode 216 is a layer formed above the electron transport layer 212 and is made, for example, of Ti. When this emission electrode 216 is provided, the bias voltage can be applied to the light absorbing layer 210 and the electron transport layer 212. In the present embodiment, the emission electrode 216 is formed on the contact layer 214 and is made as an electrode on the photoelectron emission side. The emission electrode 216 can have the thickness of not less than 5 nm nor more than 1000 nm. The material of the emission electrode 216 can be one of Al, Pt, Ag, Au, Cr, and alloys of these, in addition to Ti.

(Operation of Semiconductor Photocathode)

Next, the operation of the semiconductor photocathode will be described. For applying the backward bias voltage from the outside, as shown in FIG. 5, the higher-potential terminal of bias power supply 250 is connected to the emission electrode 216 and the lower-potential terminal to the entrance electrode 206.

In the semiconductor photocathode 200 connected in this manner, when incident light impinges on the transparent substrate 202 in a state in which the bias voltage is applied, a part thereof is reflected or absorbed by the entrance electrode 206 and the window layer 208, and the rest reaches the light absorbing layer 210. Then electrons generated through photoelectric conversion in the light absorbing layer 210 are emitted from the surface of the electron transport layer 212 to the outside.

(Production Method of Semiconductor Photocathode)

A method of producing the semiconductor photocathode according to the present embodiment will be described below. FIGS. 6 and 7 are sectional views showing the production process of the semiconductor photocathode 200.

First, an InP substrate 220 is prepared. Then an etching stop layer 218 of InGaAs, the contact layer 214 (e.g., n-type InP), the electron transport layer 212 (e.g., Be-doped p-type InP), the light absorbing layer 210 (e.g., Be-doped p-type InGaAs), and the window layer 208 (e.g., Be-doped p-type InP) are sequentially epitaxially grown on the InP substrate 220 by MBE. Subsequently, the entrance electrode 206 (e.g., tungsten) is vacuum-evaporated on the window layer 208 (FIG. 6(a)).

Next, the intermediate layer 204 (e.g., silicon dioxide film) is deposited by plasma CVD and thereafter this wafer is bonded to the transparent substrate 202 (e.g., glass) by thermal compression bond (FIG. 6(b)).

The wafer integrated with the transparent substrate 202 is immersed in heated hydrochloric acid to be etched, thereby removing all the InP substrate 220. This etching step automatically stops at the etching stop layer 218 (FIG. 6(c)).

Thereafter, the etching stop layer 218 is etched with a sulfuric acid type etchant to fabricate a substrate with the contact layer 214 as a front surface and the transparent substrate 202 as a back surface (FIG. 7 (a)).

Then the emission electrode 216 is vacuum-evaporated and stripe patterns are formed in the electron transport layer 212, contact layer 214, and emission electrode 216 by photolithography and RIE dry etching (reactive ion etching). This step results in forming electron emitting portions for emitting electrons to the outside of the semiconductor photocathode 200, in the electron transport layer 212 (FIG. 7(b)).

Finally, the entrance electrode 206 is exposed by photolithography and chemical etching with a hydrochloric acid and sulfuric acid type etchant, thereby fabricating the semiconductor photocathode 200 shown in FIG. 5 (FIG. 7(c)).

(Characteristics of Semiconductor Photocathode)

FIG. 8 shows characteristic data of the semiconductor photocathode 200 according to the second embodiment. In FIG. 8, graph G1 indicates the backward voltage-current characteristics of the semiconductor photocathode 200 including the window layer 208, the light absorbing layer 210, and the electron transport layer 212 doped with Be as a p-type impurity. In FIG. 8, for comparison, graph G2 indicates the backward voltage-current characteristics of the semiconductor photocathode including the window layer, the light absorbing layer, and the electron transport layer doped with Zn as a p-type impurity and made by the conventional method.

As apparent from FIG. 8, the backward voltage soon breaks down with the semiconductor photocathode made by the conventional method and indicated by graph G2, whereas the semiconductor photocathode of the second embodiment indicated by graph G1 shows the exceptional withstand voltage characteristics. This is conceivably because the abnormal diffusion, which occurred before with Zn being used as a dopant, is suppressed in the second embodiment.

FIG. 9 shows characteristic data of the semiconductor photocathode 200 according to the second embodiment. In FIG. 9, graph G1 indicates the quantum efficiency of the semiconductor photocathode 200 including the window layer 208, the light absorbing layer 210, and the electron transport layer 212 doped with Be as a p-type impurity. In FIG. 9, for comparison, graph G2 indicates the quantum efficiency of the semiconductor photocathode including the window layer, the light absorbing layer, and the electron transport layer doped with Zn as a p-type impurity and made by the conventional method.

As shown in FIG. 9, it is seen that the quantum efficiency is drastically improved by one figure or more with the semiconductor photocathode 200 of the second embodiment indicated by graph G1, when compared to that with the semiconductor photocathode by the conventional method indicated by graph G2. This is conceivably because the abnormal diffusion, which occurred before with Zn being used as a dopant, is suppressed in the second embodiment. The semiconductor photocathode 200 shows a flat tendency with a small fluctuation range of sensitivity in a wide wavelength band from the ultraviolet region of 350 nm to 1650 nm. Particularly, a flat tendency with higher sensitivity and with a smaller fluctuation range is achieved in the wavelength region from 450 nm to 1600 nm.

(Effects of Semiconductor Photocathode)

The following will describe the effects of the semiconductor photocathode 200 of the second embodiment having the above-described configuration. The semiconductor photocathode 200 of the second embodiment uses Be or C, which has the diffusion coefficient smaller than that of Zn or which has the atomic radius smaller than that of Zn, as the impurity of the p-type III-V compound semiconductor material, whereby the abnormal diffusion of the p-type impurity is prevented in the electron transport layer 212.

In the second embodiment, each of the layers making the semiconductor photocathode 200 is epitaxially grown by MBE. The reason for it is that the MBE process is a suitable epitaxial growth method using Be as a p-type dopant.

Furthermore, in the semiconductor photocathode 200 of the second embodiment, in order to form the light absorbing layer 210, the window layer 208 to be lattice-matched with the semiconductor material of the light absorbing layer 210 is formed under the light absorbing layer 210, and the thickness of the window layer 208 is very small. For this reason, in the applied state of the bias voltage, light having passed through the transparent substrate travels through the entrance electrode and without being blocked by the window layer, in a wide wavelength band from the ultraviolet region to the near-infrared region, to enter the light absorbing layer to excite photoelectrons. Therefore, the semiconductor photocathode is obtained with flat sensitivity for light in the wide wavelength band.

In other words, the semiconductor photocathode 200 allows not only the light in the near-infrared region of more than 780 nm but also the light in the visible region and in the ultraviolet region of 350 nm to 450 nm to reach the light absorbing layer 210 in the applied state of the bias voltage. Since this permits one semiconductor photocathode to have the sensitivity to the wide wavelength band from the ultraviolet region to the near-infrared region, there is no need for use of separate photocathodes according to wavelengths of light to be detected, when incorporated in an electron tube such as a photomultiplier tube, an image intensifier, and a streak tube. Therefore, when the semiconductor photocathode 200 is used, for example, for measurement of fluorescence, an improvement is made in degradation of accuracy due to preparation of separate photodetectors for excitation light and for fluorescence, the structure of a measuring system can be made simpler, and it is thus feasible to realize downsizing and cost reduction.

Specifically, excitation light pulses (generally, the wavelength thereof is shorter than that of fluorescence) and fluorescence can be measured simultaneously in time-resolved fluorometry, and it is thus feasible to realize downsizing and cost reduction of the system as well as an improvement in measurement accuracy. When it is combined with a compact, maintenance-free cooling device, we can produce a photodetector adaptable for a wide wavelength band.

Since in the semiconductor photocathode 200 of the second embodiment the contact layer 214 is provided to lower the contact resistance between the electron transport layer 212 and the emission electrode 216, the bias voltage can be effectively applied.

### Third Embodiment

Next, a transmission type semiconductor photocathode 300 according to the third embodiment of the present invention will be described.

FIG. 10 is a sectional view of the transmission type semiconductor photocathode 300 according to the third embodiment. A plan view of the semiconductor photocathode 300 is similar to FIG. 4 and thus the description is omitted by denoting corresponding elements by corresponding reference numerals in FIG. 4.

The third embodiment is different in the entrance electrode 306 located on the light entrance side, from the second embodiment, but the other elements are the same as those in the second embodiment. In the third embodiment, the entrance electrode 306 is different from that in the second embodiment in that the entrance electrode 306 is constructed as a metal material layer having apertures 306B. Specifically, as shown in FIG. 11 being a plan view of the entrance electrode 306, the entrance electrode 306 is provided with a plurality of apertures 306B, whereby the entrance electrode 306 is patterned in a stripe pattern.

There are no particular restrictions on the metal material making the entrance electrode 306, but the entrance electrode 306 can be made of a material such as W (tungsten), Mo (molybdenum), Ni (nickel), Ti (titanium), or Cr (chromium) as the entrance electrode 206 in the second embodiment can. There are no particular restrictions on the thickness of the entrance electrode 306, but, where tungsten is used as the metal material, the thickness can be 100 nm.

The semiconductor photocathode 300 of this configuration can be operated with application of the bias voltage by bias voltage supply 250 in the same manner as in the case of the second embodiment. Since in the third embodiment there are the plurality of apertures 306B in the stripe pattern, the light incident into the transparent substrate 202 is blocked almost 100% on linear portions 306A and edge portion 306C, while it passes through the apertures 306B, without being blocked thereby. Therefore, the light having passed through the transparent substrate 202 is passed toward the light absorbing layer 210.

In the present embodiment there are no particular restrictions on the number of apertures 306B, but, in order to achieve efficient passage of the light having passed through the transparent substrate 202, it is preferable that an aperture rate β as defined by the formula below should be made as large as possible, where the line width of the leaner portions 306A is w₁ and the pitch width of the apertures 306B is w₂.

β={1−(w₁/w₂)}×100 (Formula)

As an example, the line width w₁ of the linear portions 306A can be 5000 nm and the pitch w₂ of the apertures 306B can be 100000 nm. In this case, the aperture rate β is 95%.

The apertures 306B preferably have the line width w₁ of not less than 500 nm nor more than 50000 nm and the pitch w₂ of not less than 500 nm nor more than 500000 nm. When the line width w₁ and the pitch w₂ are set in these ranges, the bias voltage can be effectively applied to the semiconductor photocathode 300 and the apertures can be formed with good repeatability by photolithography. FIG. 11 shows the case where the plurality of apertures 306B are arranged in the stripe pattern, but the plurality of apertures may be arranged in any other pattern such as a mesh pattern or a concentric pattern.

A production method of the semiconductor photocathode 300 according to the third embodiment is much the same as that of the semiconductor photocathode 200 according to the second embodiment. However, it is different from the method in the second embodiment in that a step of forming the plurality of apertures 306B by photolithography and RIE dry etching, is added after the step of vacuum-evaporating the entrance electrode 206 on the window layer 208 as shown in FIG. 6(a).

### Fourth Embodiment

Next, a transmission type semiconductor photocathode 400 according to the fourth embodiment of the present invention will be described. A plan view and a sectional view of the semiconductor photocathode 400 according to the fourth embodiment are the same as those of the semiconductor photocathode 200 of the second embodiment and the description is omitted by denoting corresponding elements by corresponding reference numerals.

The fourth embodiment is different from the second embodiment, in the entrance electrode 406 (cf. FIG. 5) provided on the light entrance side in the semiconductor photocathode 400, and the other elements are the same as those in the second embodiment. Specifically, the fourth embodiment is different from the second embodiment in that the entrance electrode 406 is made of a transparent electroconductive material. The transparent electroconductive material can be at least one material selected from the group consisting of ITO, ZnO, In₂O₃, and SnO₂. ITO, ZnO, In₂O₃, and SnO₂ all are transparent oxide semiconductors. The thickness of the entrance electrode 406 is preferably not less than 100 nm nor more than 5000 nm and more preferably not less than 200 nm nor more than 1000 nm.

The semiconductor photocathode 400 of this configuration can be operated with application of the bias voltage by bias voltage supply 250 in the same manner as in the case of the second embodiment. Since in the fourth embodiment the entrance electrode 406 is made of the transparent electroconductive material, it has the function as an electrode and the property of transmitting light. Therefore, it is able to transmit the light having passed through the transparent substrate 202, toward the light absorbing layer 210.

A production method of the semiconductor photocathode 400 according to the fourth embodiment is much the same as that of the semiconductor photocathode 200 according to the second embodiment. However, it is different from the method in the second embodiment in that the entrance electrode 406 of the transparent electroconductive material is formed, instead of the entrance electrode 206 of the metal material, in the step of vacuum-evaporating the entrance electrode 206 on the window layer 208 as shown in FIG. 6(a).

The present invention, which was described above with an example of the description through the first embodiment to the fourth embodiment, has been accomplished based on the new findings as described below.

The inventor conducted elaborate research and found out the fact as described below. Namely, the inventor discovered the following fact: “In a semiconductor device, e.g., a semiconductor photocathode or the like, using Zn as a p-type dopant and having a heterostructure, where a semiconductor layer of a p-type binary compound semiconductor (binary semiconductor layer, or the first III-V compound semiconductor layer) doped with Zn in the low concentration of not more than 1×10¹⁸ cm⁻³ is deposited on a semiconductor layer of a p-type ternary compound semiconductor or a semiconductor layer of a p-type quaternary compound semiconductor (ternary/quaternary semiconductor layer, or the second III-V compound semiconductor layer) doped with Zn in the low concentration of not more than 1×10¹⁸ cm⁻³, the predetermined Zn doping concentration as designed is achieved as proved by analysis of concentration distribution after deposition. However, when the ternary/quaternary semiconductor layer is deposited on the binary semiconductor layer contrary to the above, the abnormal diffusion of Zn occurs in the binary semiconductor layer as proved by analysis of concentration distribution after deposition and the predetermined Zn doping concentration as designed is not achieved in the binary semiconductor layer.”

The inventor conducted further elaborate research and further discovered the following fact: “When a semiconductor device is formed in a configuration wherein it has a first III-V compound semiconductor layer and a second III-V compound semiconductor layer making a heterojunction and wherein the energy gap of the second III-V compound semiconductor layer is smaller than that of the first III-V compound semiconductor layer, the abnormal diffusion of the p-type impurity does not occur from a growth system or growth conditions, but occurs from the essential problems arising from the semiconductor heterostructure and the type of the p-type impurity.” There are no prior art documents pointing out this problem of abnormal diffusion and no reason for it has been elucidated. The present invention has been accomplished on the basis of the new findings as described above and in order to prevent the abnormal diffusion of the p-type impurity in the low concentration region in the case where the ternary/quaternary semiconductor layer is deposited on the binary semiconductor layer.

The above contents will be described below in more detail. First, the inventor experimentally manufactured a semiconductor device of a heterostructure (which will also be referred to hereinafter as a “first prototype device”) by metal organic vapor phase epitaxy (hereinafter referred to as “MOCVD”). The first prototype device has the structure in which a p-type InP substrate, a p-type InP semiconductor layer (first layer), a p-type InGaAsP semiconductor layer (second layer), a p-type InP semiconductor layer (third layer), and an n-type InP semiconductor layer (fourth layer) are stacked in order.

FIG. 12 is a drawing showing a table of the designed particulars of the materials, thicknesses, etc. of the respective layers, for experimentally manufacturing the first prototype device. In the first prototype device with the heterostructure, as shown in FIG. 12, the InP substrate is so designed that its thickness is 350 μm and that the doping concentration of Zn is 5×10¹⁶ cm⁻³. The first layer is so designed that its thickness is 1 μm and that the doping concentration of Zn is 2×10¹⁸ cm⁻³. The second layer is so designed that its wavelength is 1.7 μm, that its thickness is 2 μm, and that the doping concentration of Zn is 2×10¹⁶ cm⁻³. The third layer is so designed that its thickness is 0.7 μm and that the doping concentration of Zn is 2×10¹⁶ cm⁻³. The fourth layer is so designed that its thickness is 0.2 μm and that the doping concentration of silicon (Si) is 2×10¹⁸ cm⁻³.

Based on the above design, each of the layers was epitaxially grown in order by MOCVD, thereby manufacturing the first prototype device experimentally. FIG. 13 is a drawing showing the result of measurement to measure the concentration distribution of Zn atoms as the p-type dopant in the first prototype device by SIMS. In FIG. 13 the measurement result is shown in the form similar to that in FIG. 3 described above, wherein the concentration distribution of Zn atoms is indicated by graph G1, the concentration distribution of As atoms by graph G2, and the concentration distribution of P atoms by graph G3. As shown in FIG. 13, the measured doping concentrations of Zn in the respective layers agree with the doping concentrations of Zn (in the fifth column in FIG. 12) according to the design shown in FIG. 12. Particularly, noting the part of the p-type InP layer of the third layer encircled by a dotted line in FIG. 13, it can be confirmed that the atomic concentration of Zn is the predetermined value of 2×10¹⁶ cm⁻³ as designed.

With respect to the first prototype device with the as-designed doping concentrations confirmed as described above, the inventor experimentally manufactured another semiconductor device of a heterostructure (which will also be referred to as a “second prototype device”) in the same manner by MOCVD. The second prototype device has the structure in which an n-type InP substrate, an n-type InP semiconductor layer (first layer), an n-type InGaAsP semiconductor layer (second layer), an n-type InP semiconductor layer (third layer), a p-type InP semiconductor layer (fourth layer), a p-type InGaAsP semiconductor layer (fifth layer), and a p-type InP semiconductor layer (sixth layer) are stacked in order.

Namely, the first prototype device with the heterostructure has the structure in which the p-type InP layer (third layer, or p-type binary semiconductor layer) is deposited on the p-type InGaAsP layer (second layer, or p-type ternary/quaternary semiconductor layer), whereas the second prototype device with the heterostructure as well has the structure in which the p-type InGaAsP layer (fifth layer, or p-type ternary/quaternary semiconductor layer) is deposited on the p-type InP layer (fourth layer, or p-type binary semiconductor layer) on the n-type InP semiconductor layer (third layer).

FIG. 14 is a drawing showing a table of the designed particulars of the materials, thicknesses, etc. of the respective layers, for experimentally manufacturing the second prototype device. In the second prototype device with the heterostructure, as shown in FIG. 14, the InP substrate is so designed that its thickness is 350 μm and that the doping concentration of S is 2×10¹⁸ cm⁻³. The first layer is so designed that its thickness is 1 μm and that the doping concentration of Si is 2×10¹⁸ cm⁻³. The second layer is so designed that its wavelength is 1.7 μm, that its thickness is 2 μm, and that the doping concentration of Si is 2×10¹⁸ cm-⁻³.

The third layer is so designed that its thickness is 0.2 μm and that the doping concentration of Si is 2×10¹⁸ cm⁻³. The fourth layer is so designed that its thickness is 0.7 μm and that the doping concentration of Zn is 2×10¹⁶ cm⁻³. The fifth layer is so designed that its wavelength is 1.7 μm, that its thickness is 2 μm, and that the doping concentration of Zn is 2×10¹⁶ cm⁻³. The sixth layer is so designed that its thickness is 0.05 μm and that the doping concentration of Zn is 2×10¹⁸ cm⁻³.

Based on the above design, each of the layers was epitaxially grown in order by MOCVD, thereby manufacturing the second prototype device experimentally. FIG. 15 is a drawing showing the result of measurement to measure the concentration distribution of Zn atoms as the p-type dopant in the second prototype device by SIMS. In FIG. 15 the measurement result is illustrated in the form similar to that in FIG. 13 described above. As shown in FIG. 15, the measured doping concentrations of Zn in the respective layers do not agree with the as-designed doping concentrations of Zn (in the fifth column in FIG. 14) shown in FIG. 14. Particularly, noting the part of the p-type InP layer of the fourth layer encircled by a dotted line in FIG. 15, its Zn atom concentration is not more than 1×10¹⁵ cm⁻³ which is the measurement limit of SIMS.

It is understood from this result that the result shown in FIG. 15, different from the result of FIG. 13, indicates that the Zn concentration in the p-type InP layer of the fourth layer in the second prototype device is not 2×10¹⁶ cm⁻³, which was the predetermined atomic concentration as designed. It can also be seen from the result in FIG. 15 that Zn atoms are segregated at the interface to the n-type InP layer of the third layer in the second prototype device. The same result was confirmed through repetitive operations of the epitaxial growth and analysis. The same result was also obtained with devices fabricated by epitaxial growth under different conditions, e.g., different temperatures or gas flow rates, with another MOCVD system.

These results infer the following: “in the semiconductor device with Zn as a p-type dopant and with the heterostructure wherein the p-type binary semiconductor layer doped with Zn in the low concentration of not more than 1×10¹⁸ cm⁻³ is deposited on the p-type ternary/quaternary semiconductor layer doped with Zn in the low concentration of not more than 1×10¹⁸ cm⁻³, or in the case of the first prototype device, the predetermined Zn doping concentration as designed is achieved as proved by analysis of the concentration distribution after deposition. However, when the ternary/quaternary semiconductor layer is deposited on the binary semiconductor layer contrary to the above, or in the case of the second prototype device, the abnormal diffusion of Zn occurs in the binary semiconductor layer, irrespective of the growth systems and growth conditions, as proved by analysis of concentration distribution after deposition, and the predetermined Zn doping concentration as designed is not achieved in the binary semiconductor layer.”

In the case of the second prototype device, even if the Zn doping concentration in the p-type InP layer of the fourth layer was designed to be higher, e.g., 1×10 cm⁻³, the predetermined atomic concentration as designed was not achieved in the p-type InP layer of the fourth layer and the measured concentration was not more than the measurement limit of SIMS. This result infers that “the abnormal diffusion of Zn occurs independent of the doping concentration.”

With occurrence of such abnormal diffusion of the p-type dopant, there will arise the problem that it is impossible to accurately control the carrier concentration in the semiconductor layer suffering the abnormal diffusion and, as a result, an electronic device or an optical device fabricated with the semiconductor layer, for example, as a photosensitive layer of a semiconductor light receiving device or as a light emitting layer of a semiconductor light emitting device fails to hold as-expected characteristics.

Subsequently, the inventor experimentally manufactured still another semiconductor device (which will also be referred to as a “third prototype device”) by MOCVD in the same manner as in the case of the first prototype device and the second prototype device. FIG. 16 is a drawing showing a table of the designed particulars of the materials, thicknesses, etc. of the respective layers, for manufacturing the third prototype device experimentally. As shown in FIG. 16, the third prototype device manufactured experimentally is different in the third layer and the fourth layer from the second prototype device shown in FIG. 14.

Namely, the third layer of the n-type InGaAsP semiconductor layer is so designed that its wavelength is 0.95 μm, that its thickness is 0.2 μm, and that the doping concentration of Si is 2×10¹⁸ cm⁻³. The fourth layer of the p-type InGaAsP semiconductor layer is so designed that its wavelength is 0.95 μm, that its thickness is 0.7 μm, and that the doping concentration of Zn is 2×10¹⁶ cm⁻³. In this manner, the third prototype device is so designed that, instead of the p-type InP layer of the fourth layer which suffered the abnormal diffusion of Zn in the second prototype device, the fourth layer is the p-type InGaAsP layer having the energy gap close to that of the p-type InP layer and larger than that of the p-type InGaAsP semiconductor layer of the fifth layer.

With this third prototype device, the concentration distribution of Zn atoms as the p-type dopant was measured by SIMS, and the result thereof was similar to FIG. 15 described above. Namely, the measured doping concentrations of Zn in the respective layers disagreed with the as-designed Zn doping concentrations in FIG. 16 (in the fifth column in FIG. 16). The same result was confirmed through repetitive operations of the epitaxial growth and analysis. The same result was also obtained with devices fabricated by epitaxial growth under different conditions, e.g., different temperatures or gas flow rates with another MOCVD system.

It is believed from the results of the experiments with the first prototype device, the second prototype device, and the third prototype device as described above that “when the semiconductor device is so constructed that it has the first III-V compound semiconductor layer and the second III-V compound semiconductor layer making the heterojunction and that the energy gap of the second III-V compound semiconductor layer is smaller than that of the first III-V compound semiconductor layer, the abnormal diffusion of the p-type impurity does not occur from the growth system or the growth conditions, but does occur from the essential problems arising from the semiconductor heterostructure and the type of the p-type impurity.” There were no prior art documents or patent documents pointing out the problem of such abnormal diffusion, and the reason for it has not been elucidated.

The present invention has been accomplished based on the new findings as described above and in order to prevent the abnormal diffusion of the p-type impurity in the low concentration region in the case where the ternary/quaternary semiconductor layer is deposited on the binary semiconductor layer.

What is claimed is:

1. A semiconductor photocathode comprising a first III-V compound semiconductor layer and a second III-V compound semiconductor layer doped with a p-type impurity and joined to each other to make a heterojunction;
wherein the second III-V compound semiconductor layer functions as a light absorbing layer;
wherein an energy gap of the second III-V compound semiconductor layer is smaller than an energy gap of the first III-V compound semiconductor layer; and
wherein beryllium (Be) or carbon (C) is used as the p-type dopant in the first III-V compound semiconductor layer and the second III-V compound semiconductor layer.

2. The semiconductor photocathode according to claim 1, wherein the second III-V compound semiconductor layer is deposited on the first III-V compound semiconductor layer.

3. The semiconductor photocathode according to claim 1, wherein the first III-V compound semiconductor layer and the second III-V compound semiconductor layer contain at least one from each group of (In, Ga, Al) and (As, P, N).

4. The semiconductor photocathode according to claim 1, wherein the first III-V compound semiconductor layer is a III-V compound semiconductor layer of a binary compound semiconductor, and
wherein the second III-V compound semiconductor layer is a III-V compound semiconductor layer of a ternary compound semiconductor or a quaternary compound semiconductor.

5. The semiconductor photocathode according to claim 1, wherein the first III-V compound semiconductor layer and the second III-V compound semiconductor layer are grown by molecular beam epitaxy.

6. The semiconductor photocathode according to claim 1, wherein the first III-V compound semiconductor layer and the second III-V compound semiconductor layer are doped with the p-type impurity in a low concentration of not more than 1×10¹⁸ cm⁻³.

7. The semiconductor photocathode according to claim 1, comprising:
a transparent substrate:
an entrance electrode formed above the transparent substrate and permitting passage of light having passed through the transparent substrate;
said light absorbing layer of the second III-V compound semiconductor layer formed above the entrance electrode and adapted for exciting photoelectrons in response to incidence of light;
a window layer of a p-type III-V compound semiconductor material interposed between the entrance electrode and the light absorbing layer, having an energy gap larger than that of the light absorbing layer, comprised of a semiconductor material to be lattice-matched with the light absorbing layer, and having a thickness of not less than 10 nm nor more than 200 nm;
an electron transport layer of the first III-V compound semiconductor layer formed on the light absorbing layer, comprised of a semiconductor material to be lattice-matched with the light absorbing material, and adapted for emitting the photoelectrons excited in the light absorbing layer, from a surface thereof to the outside; and
an emission electrode formed above the electron transport layer.

8. The semiconductor photocathode according to claim 1, comprising:
a transparent substrate:
an entrance electrode formed above the transparent substrate and permitting passage of light having passed through the transparent substrate;
said light absorbing layer of the second III-V compound semiconductor layer formed above the entrance electrode and adapted for exciting photoelectrons in response to incidence of light;
a window layer of a p-type III-V compound semiconductor material interposed between the entrance electrode and the light absorbing layer, having an energy gap larger than that of the light absorbing layer, comprised of a semiconductor material to be lattice-matched with the light absorbing layer, and having a thickness of not less than 10 nm nor more than 200 nm;
an electron transport layer of the first III-V compound semiconductor layer formed on the light absorbing layer, comprised of a semiconductor material to be lattice-matched with the light absorbing material, and adapted for emitting the photoelectrons excited in the light absorbing layer, from a surface thereof to the outside;
an emission electrode formed above the electron transport layer; and
a contact layer of an n-type III-V compound semiconductor material formed between the electron transport layer and the emission electrode.

9. The semiconductor photocathode according to claim 7, wherein the entrance electrode is a metal material having a thickness of not less than 5 nm nor more than 100 nm.

10. The semiconductor photocathode according to claim 7, wherein the entrance electrode is a metal material having a thickness of not less than 10 nm nor more than 50 nm.

11. The semiconductor photocathode according to claim 7, wherein the entrance electrode is a metal material layer having an aperture.

12. The semiconductor photocathode according to claim 7, wherein the entrance electrode is a layer of at least one transparent electroconductive material selected from a group consisting of ITO, ZnO, In₂O₃, and SnO₂.

13. The semiconductor photocathode according to claim 7, wherein the thickness of the window layer is not less than 20 nm nor more than 100 nm.

14. The semiconductor photocathode according to claim 7, further comprising an insulating film or an antireflection film interposed between the transparent substrate and the entrance electrode.

15. The semiconductor photocathode according to claim 8, wherein the entrance electrode is a metal material having a thickness of not less than 5 nm nor more than 100 nm.

16. The semiconductor photocathode according to claim 8, wherein the entrance electrode is a metal material having a thickness of not less than 10 nm nor more than 50 nm.

17. The semiconductor photocathode according to claim 8, wherein the entrance electrode is a metal material layer having an aperture.

18. The semiconductor photocathode according to claim 8, wherein the entrance electrode is a layer of at least one transparent electroconductive material selected from a group consisting of ITO, ZnO, In₂O₃, and SnO₂.

19. The semiconductor photocathode according to claim 8, wherein the thickness of the window layer is not less than 20 nm nor more than 100 nm.

20. The semiconductor photocathode according to claim 8, further comprising an insulating film or an antireflection film interposed between the transparent substrate and the entrance electrode.
